(19) United States
(12) Patent Application Publication
(10) Pub. No.: US 2023/0085592 A1
(43) Pub. Date: Mar. 16, 2023

(54) SUBSTRATE PROCESSING APPARATUS AND SUBSTRATE PROCESSING METHOD

(71) Applicant: JUSUNG ENGINEERING CO., LTD., Gwangju-si, Gyeonggi-do (KR)

(72) Inventors: Ji Hun LEE, Gwangju-si, Gyeonggi-do (KR); Jong Sik KIM, Gwangju-si, Gyeonggi-do (KR)

(21) Appl. No.: 17/797,424

(22) PCT Filed: Feb. 2, 2021
(86) PCT No.: PCT/KR2021/001361

§ 371 Date: Aug. 3, 2022

(30) Foreign Application Priority Data
Feb. 3, 2020 (KR) 10-2020-0012793

(51) Int. Cl. H01J 37/32; C23C 16/458; C23C 16/455; C23C 16/509

(52) U.S. Cl. CPC H01J 37/32568; H01J 37/32449; H01J 37/32082; H01J 37/32541; H01J 37/32724; C23C 16/4584; C23C 16/45574; C23C 16/509; C23C 16/4586; C23C 16/45536; C23C 16/45544; H01J 2237/20214; H01J 2237/201; H01J 2237/332

(57) ABSTRACT

The present disclosure relates to a substrate processing apparatus and method. The substrate processing apparatus and method can sequentially inject process gases onto substrates located in first and second spaces obtained by dividing the internal space of a chamber in the substrate processing apparatus, thereby forming thin films with uniform thicknesses on the substrates located in the first and second spaces.

### BACKGROUND

### 1. Technical Field

The present disclosure relates to a substrate processing apparatus and method, and more particularly, to a substrate processing apparatus and method which can sequentially inject process gases onto substrates located in first and second spaces obtained by dividing the internal space of a chamber of the substrate processing apparatus, thereby forming thin films with a uniform thickness.

### 2. Related Art

In general, a thin film deposition process, a photolithography process, an etching process and the like are performed in order to fabricate a semiconductor device, and each of the processes is performed in a chamber designed as the optimal environment for the corresponding process. The thin film deposition process refers to a process of forming thin films by depositing a raw material on a silicon wafer, the photolithography process refers to a process of exposing or concealing a region selected among the thin films using a photosensitive material, and the the thin films using a photosensitive material, and the etching process refers to a process of patterning the selected region in a desired manner by removing the thin film of the selected region.

As a thin film deposition device for forming a predetermined thin film on a silicon wafer, various devices such as a CVD (Chemical Vapor Deposition) device and ALD (Atomic Layer Deposition) device are used. The thin film deposition device is applied to various fields for fabricating semiconductors. Recently, with the rapid decrease in design rule of semiconductor devices, a thin film with a fine pattern has been demanded. Thus, the use of an ALD device capable of uniformly forming a fine pattern with an atomic layer thickness is increasing.

The CVD device deposits a reaction product on a substrate, the reaction product being generated on the substrate by injecting a plurality of gas molecules into a process chamber at the same time. However, the ALD device deposits a chemical reaction product on only the top surface of a substrate by injecting one gas material into a process chamber, leaving only the gas physically adsorbed on the top of the heated substrate by purging the gas material, and then injecting another gas material.

Among the deposition devices, the ALD device can deposit a nano thin film having excellent uniformity. Thus, much attention is being paid to the ALD device as a deposition technology required for fabricating a nano-scale semiconductor device. In particular, the ALD device can precisely control the thickness of a thin film in Angstrom units. Therefore, the ALD device has excellent step coverage, and can uniformly deposit even a complex 3D structure, and precisely control the thickness and composition of the thin film. Thus, the ALD device can deposit a material across a large area at uniform speed.

A conventional substrate processing apparatus to which the ALD device is applied includes a substrate support unit for supporting a substrate and a gas injection unit disposed at the top of the substrate support unit and configured to inject a process gas.

At this time, the gas injection unit injects a source gas onto the top of the substrate mounted on the substrate support unit, and then injects a purge gas to purge the top of the substrate. Subsequently, the process of injecting a reactant gas onto the top of the substrate and then injecting the purge gas to purge the top of the substrate again is repeatedly performed to form a uniform thin film on the top of the substrate.

However, the conventional ALD device has a problem in that, since the thin film is deposited by sequentially injecting the source gas and the reactant gas onto one substrate within the chamber, the productivity is decreased.

Even when a plurality of substrates are processed, thin film deposition is performed at positions where substrates located in first and second spaces are fixed. In this case, a structural problem within the chamber or the influence of a heater terminal formed on the substrate support unit may change the uniformity of thin films deposited on the plurality of substrates located in the first and second spaces.

### SUMMARY

Various embodiments are directed to a substrate processing apparatus and method which can repeat a process of independently forming thin films in first and second spaces, which are obtained by dividing the internal space of a chamber of a substrate processing apparatus and do not overlap each other, by injecting process gases onto first and second substrates located in the first and second spaces, respectively, changing the positions of the first and second substrates by rotating a susceptor, by which the plurality of substrates are supported, at a predetermined angle after the thin films with a predetermined thickness are formed, and injecting process gases again to form thin films with a predetermined thickness, and thus minimize the influence of positions in the first and second spaces, thereby forming thin films with uniform thicknesses.

In an embodiment, a substrate processing apparatus may include: a chamber including a first space and a second space which does not overlap the first space; a rotatable susceptor arranged across the first and second spaces in the chamber, and configured to support one or more substrates in the first space and support one or more substrates in the second space; a first injection unit facing the susceptor in the first space, and configured to inject two or more different gases into the first space; and a second injection unit facing the susceptor in the second space, and configured to inject two or more different gases into the second space, wherein each of the first and second injection units includes: a first gas inject flow path configured to inject a first gas; and a second gas inject flow path configured to inject a second gas different from the first gas.

In an embodiment, there is provided a substrate processing method for processing a substrate by using a substrate processing apparatus which includes: a chamber including a first space and a second space that does not overlap the first space; a rotatable susceptor arranged across the first and second spaces in the chamber, and configured to support one or more substrates in the first space and support one or more substrates in the second space; a first injection unit facing the susceptor in the first space, and configured to inject two or more different gases into the first space; and a second injection unit facing the susceptor in the second space, and configured to inject two or more different gases into the second space. The substrate processing method may include: a substrate arranging step of arranging one or more first substrates and one or more second substrates under the first injection unit and the second injection unit, respectively; a first thin film forming step of repeating, one or more times, a process of sequentially injecting a source gas and a reactant gas toward the first and second substrates through the first and second injection units, respectively; a first susceptor rotating step of moving the first substrate to under the second injection unit and moving the second substrate to under the first injection unit, by rotating the susceptor at a predetermined angle; and a second thin film forming step of repeating, one or more times, a process of sequentially injecting the source gas and the reactant gas toward the second substrate and the first substrate through the first injection unit and the second injection unit, respectively.

In an embodiment, there is provided a substrate processing method for processing a substrate by using a substrate processing apparatus which includes: a chamber including a first space and a second space that does not overlap the first space; a rotatable susceptor arranged across the first and second spaces in the chamber, and configured to support one or more substrates in the first space and support one or more substrates in the second space; a first injection unit facing the susceptor in the first space, and configured to inject two or more different gases into the first space; and a second injection unit facing the susceptor in the second space, and configured to inject two or more different gases into the second space. The substrate processing method may include: a substrate arranging step of arranging one or more first substrates and one or more second substrates under the first injection unit and the second injection unit, respectively; and a thin film forming step of repeating, one or more times, a process of sequentially injecting a source gas and a reactant gas toward the first and second substrates through the first and second injection units, respectively, wherein the thin film forming step includes: injecting the source gas through a first gas inject flow path; and injecting the reactant gas through a second gas inject flow path different from the first gas inject flow path.

In accordance with the embodiments of the present disclosure, the substrate processing apparatus and method can repeat a process of forming thin films with predetermined thicknesses by sequentially injecting the first and second gases onto the substrates arranged in the first and second spaces, rotating the susceptor, and forming thin films with predetermined thicknesses by sequentially injecting the first and second gases onto the substrates arranged in the first and second spaces again, thereby improving the uniformity of the thin films deposited on the plurality of substrates located in the first and second spaces.

### BRIEF DESCRIPTION OF THE DRAWINGS

FIG. 1 is a diagram for describing a plan structure of the inside of a chamber in a substrate processing apparatus in accordance with an embodiment of the present disclosure.

FIG. 2A is a cross-sectional view briefly illustrating a cross-section of the chamber, taken along line B-B of FIG. 1.

FIG. 2B is an expanded cross-sectional view of a portion C in FIG. 2A.

FIG. 2C is an expanded cross-sectional view of a portion D in FIG. 2A.

FIGS. 3A and 3B are diagrams for describing a bottom plan structure of a susceptor in the substrate processing apparatus in accordance with the embodiment of the present disclosure.

FIG. 4 is a process flowchart illustrating a substrate processing method in accordance with an embodiment of the present disclosure.

FIG. 5 is a process flowchart illustrating a substrate processing method in accordance with another embodiment of the present disclosure.

### DETAILED DESCRIPTION

Hereafter, exemplary embodiments of the present disclosure will be described in detail with reference to the accompanying drawings such that the present disclosure can be easily carried out by those skilled in the art to which the present disclosure pertains. Among reference numerals marked on the respective drawings, like reference numerals represent the same components.

Moreover, in describing the present disclosure, detailed descriptions for related publicly known technologies will be ruled out in order not to unnecessarily obscure subject matters of the present disclosure.

The terms such as first and second may be used to describe various components, but the components are not limited by the terms, and the terms are used only to distinguish one component from another component.

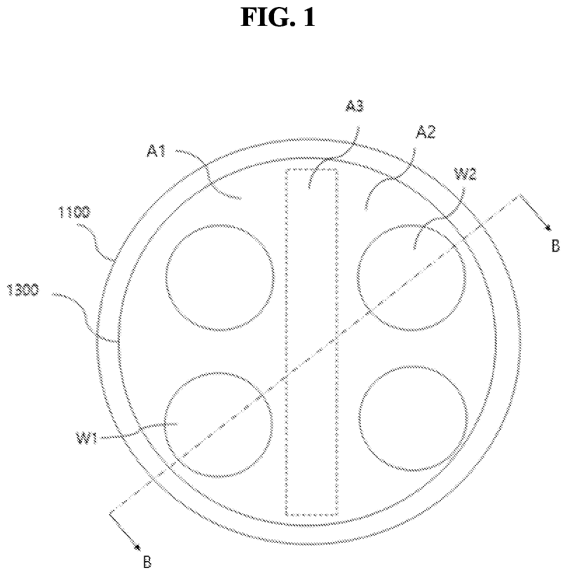

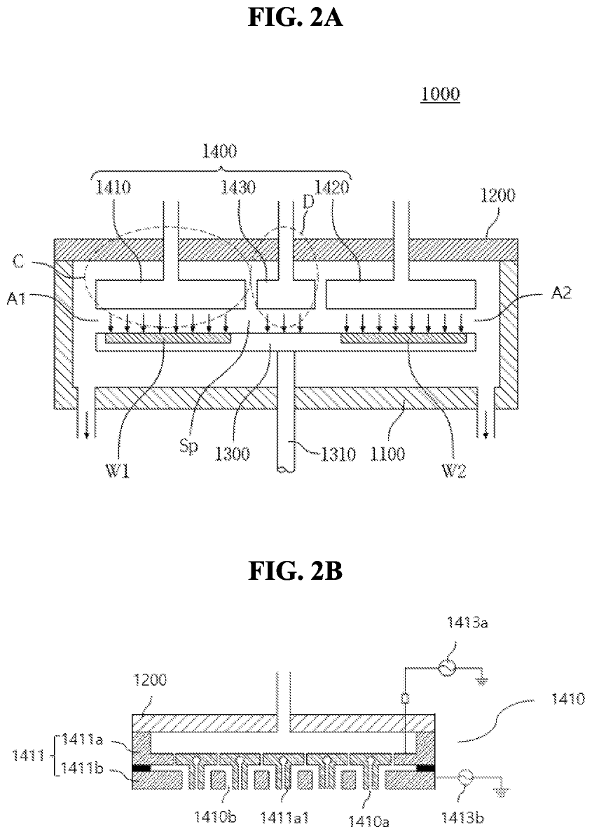

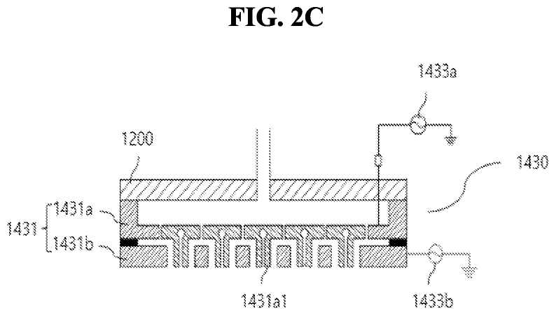

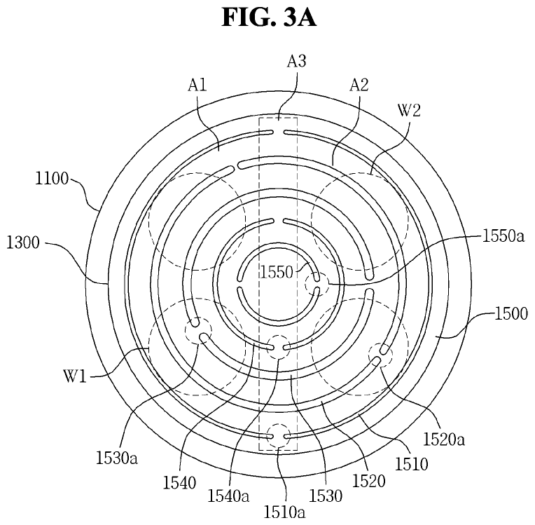

FIG. 1 is a diagram for describing a plan structure of the inside of a chamber in a substrate processing apparatus in accordance with an embodiment of the present disclosure, and FIG. 2A is a cross-sectional view briefly illustrating a cross-section of the chamber, taken along line B-B of FIG. 1. FIG. 2B is an expanded cross-sectional view of a portion C in FIG. 2A, and FIG. 2C is an expanded cross-sectional view of a portion D in FIG. 2A.

Hereafter, the substrate processing apparatus 1000 in accordance with the embodiment of the present disclosure will be described with reference to FIGS. 1 and 2A to 2C.

The substrate processing apparatus 1000 in accordance with the embodiment of the present disclosure includes a chamber 1100, a chamber lid 1200, a susceptor 1300 and a gas injection unit 1400.

The chamber 1100 in which an actual process such as thin film deposition and etching is performed on a substrate may be coupled to the chamber lid 1200 so as to form a closed reaction space. At this time, the reaction space may include a first space A1, a second space A2 and a third space A3. The third space A3 may serve as a purge space to isolate the first and second spaces A1 and A2 from each other.

The susceptor 1300 is disposed across the first and second spaces A1 and A2 within the chamber 1100, supports one or more substrates W1 in the first space A1, and supports one or more substrates W2 in the second space A2. For a process, the susceptor 1300 may be rotated around a rotating shaft 1310 at the bottom thereof in a horizontal clockwise direction or counterclockwise direction. At this time, the susceptor 1300 may be rotated at a predetermined angle in a predetermined period.

The susceptor 1300 may load a plurality of substrates W1 and W2 to positions spaced apart from each other at a predetermined angle. At this time, the spacing interval between the positions to which the substrates W1 and W2 are loaded may be decided in consideration of the arrangement interval among a first injection unit 1410, a second injection unit 1420 and a third injection unit 1430. For example, the spacing interval between the positions to which the substrates W1 and W2 are loaded may be set to the same value as the arrangement interval among a first injection unit 1410, a second injection unit 1420 and a third injection unit 1430.

The third injection unit 1430 may be configured above the susceptor 1300 based on the rotation center of the susceptor 1300, such that the third injection unit 1430 and the susceptor 1300 face each other. The third injection unit 1430 injects a purge gas to form the third space A3 which divides the inside of the chamber 1100 into the first and second spaces A1 and A2.

At the top of the first space A1 within the chamber 1100, the first injection unit 1410 is formed to face the susceptor 1300. The first injection unit 1410 serves to inject two or more different gases into the first space A1. Furthermore, at the top of the second space A2 within the chamber 1100, the second injection unit 1420 is formed to face the susceptor 1300. The second injection unit 1420 serves to inject two or more different gases into the second space A2.

The first injection unit 1410 includes a first gas inject flow path 1410a through which a first gas is injected into the first space A1 and a second gas inject flow path 1410b through which a second gas different from the first gas is injected into the first space A1. The first injection unit 1410 forms a thin film on a substrate located in the first space A1 by alternately injecting the first and second gases into the first space A1 through the first and second gas inject flow paths 1410a and 1410b. At this time, the first or second gas may be injected in a plasma state toward the substrate.

When the first gas is plasma-treated and injected, the inert first gas may be activated to generate a large quantity of radicals and ions. Therefore, the first gas can be decomposed even at low temperature, and impurities contained in the first gas itself can be effectively removed. When the second gas is plasma-treated and injected, the density of a thin film may be improved to increase the uniformity of the thin films.

Plasma may be implemented as direct plasma or remote plasma generated by applying RF power into the space where the first gas stays, depending on an electrode structure.

The first injection unit 1410 may inject a purge gas after injecting the first or second gas. The first injection unit 1410 injects a first purge gas during the time period between a point of time that the first gas is injected and a point of time that the second gas is injected, and injects a second purge gas during the time period between a point of time that the second gas is injected and a point of time that the first gas is injected. At this time, one or more of the first and second purge gases may be injected in a plasma state toward the substrate. When the first and second purge gases are plasma-treated and injected, the top, bottom and sidewalls of a pattern formed on a thin film may be selectively deposited. Furthermore, when a purge gas is plasma-treated and injected on a thin film, hydrogen included in the surface of the thin film may be removed to modify the surface of the thin film, which makes it possible to form a thin film with high selectivity.

The first injection unit 1410 may include an electrode 1411 for injecting the first gas, the second gas, the first purge gas or the second purge gas in a plasma state toward the substrate.

The electrode 1411 may include a first electrode 1411a and a second electrode 1411b. The first electrode 1411a may have a plurality of protruding electrodes 1411a1 formed thereon, and the second electrode 1411b may have openings formed at positions corresponding to the respective protruding electrodes, such that the protruding electrodes are inserted into the openings.

In order to generate plasma between the side surfaces of the protruding electrodes and the inner surfaces of the openings of the second electrode 1411b, RF power may be applied to at least any one of the first and second electrodes 1411a and 1411b by RF power supply units 1413a and 1413b.

The first gas is injected through the first gas inject flow path 1410a extended to the protruding electrode, and the second gas is injected through the second gas inject flow path 1410b between the side surface of the protruding electrode and the inner surface of the opening of the second electrode.

The second injection unit 1420 includes a first gas inject flow path through which the first gas is injected into the second space A2 and a second gas inject flow path through which the second gas different from the first gas is injected into the second space A2. The second injection unit 1420 forms a thin film on a substrate located in the second space A2 by alternately injecting the first and second gases into the second space A2 through the first and second gas inject flow paths. At this time, the first or second gas may be injected in a plasma state toward the substrate. The detailed configuration of the second injection unit 1420 is the same as the detailed configuration of the first injection unit 1410.

The second injection unit 1420 may inject the purge gas after injecting the first or second gas. The second injection unit 1420 injects the first purge gas during the time period between a point of time that the first gas is injected and a point of time that the second gas is injected, and injects the second purge gas during the time period between a point of time that the second gas is injected and a point of time that the first gas is injected. At this time, one or more of the first and second purge gases may be injected in a plasma state toward the substrate.

The second injection unit 1420 may include an electrode for injecting the first gas, the second gas, the first purge gas or the second purge gas in a plasma state toward the substrate.

The electrode may include a first electrode and a second electrode. The first electrode may have a plurality of protruding electrodes formed thereon, and the second electrode may have openings formed at positions corresponding to the protruding electrodes, such that the protruding electrodes are inserted into the openings.

In order to generate plasma between the side surfaces of the protruding electrodes and the inner surfaces of the openings of the second electrode, RF power may be applied to at least any one of the first and second electrodes.

The first gas is injected through the first gas inject flow path extended to the protruding electrode, and the second gas is injected through the second gas inject flow path between the side surface of the protruding electrode and the inner surface of the opening of the second electrode.

In the present disclosure, it is described that the first gas is a source gas, and the second gas is a reactant gas. However, the present disclosure is not limited thereto, and the first gas may be the reactant gas, and the second gas may be the source gas.

When the first and second injection units 1410 and 1420 inject the first or second gas, the susceptor 1300 may be stopped.

The chamber 1100 may further include the third space A3 between the first and second spaces A1 and A2. The third space A3 may include a third injection unit 1430 configured to inject a third purge gas toward the susceptor. At this time, the third purge gas may be injected in a plasma state toward the substrate.

The third injection unit 1430 may include an electrode 1431 for injecting the third purge gas in a plasma state toward the substrate.

The electrode 1431 may include a third electrode 1431a and a fourth electrode 1431b. The third electrode 1431a may have a plurality of protruding electrodes 1431a1 formed thereon, and the fourth electrode 1431b may have openings formed at positions corresponding to the respective protruding electrodes, such that the protruding electrodes are inserted into the openings.

In order to generate plasma between the side surfaces of the protruding electrodes and the inner surfaces of the openings of the fourth electrode 1431b, RF power may be applied to at least any one of the third and fourth electrodes 1431a and 1431b by RF power supply units 1433a and 1433b.

Through the first and second injection units 1410 and 1420, a plasma treatment may be performed on the thin film formed on the substrate. When such a plasma treatment is performed on a thin film, the electrical and optical characteristics of the deposited thin film may be improved, and the surface modification characteristic of the thin film, such as hydrophobicity or hydrophilicity, may be improved, which makes it possible to improve the uniformity of the thin films as a whole.

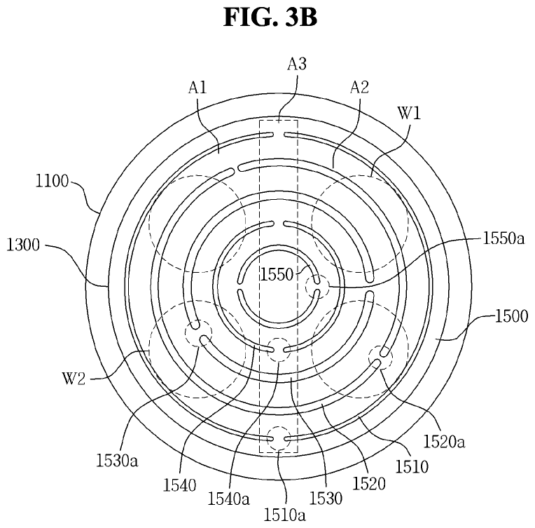

FIGS. 3A and 3B are diagrams for describing a heater arrangement structure in the susceptor of the substrate processing apparatus in accordance with the embodiment of the present disclosure.

FIG. 3A is a diagram for describing a heater arrangement structure within the susceptor of the substrate processing apparatus in accordance with the embodiment of the present disclosure, and FIG. 3B is a diagram for describing the heater arrangement structure after the susceptor of the substrate processing apparatus in accordance with the embodiment of the present disclosure is rotated by 180 degrees.

As illustrated in FIGS. 3A and 3B, the substrate processing apparatus 1000 in accordance with the embodiment of the present disclosure may further include a heater 1500 installed at the bottom of the susceptor 1300 and configured to heat the substrate. The heater 1500 may include a plurality of heater members 1510, 1520, 1530, 1540 and 1550 each configured as a thin and long pipe-shaped wire. The plurality of heater members 1510, 1520, 1530, 1540 and 1550 may form concentric patterns, and include a plurality of power supply terminals 1510a, 1520a, 1530a, 1540a and 1550a connected to an external power supply (not illustrated).

In general, the heater members and the power supply terminals of the heater may be symmetrically arranged in a concentric shape in the first and second spaces. However, when the heater members and the power supply terminals are symmetrically formed in the first and second spaces, the power supply terminals may be arranged in the same region even when the substrates which have been located in the first space are moved by the rotation of the susceptor and located in the second space. Therefore, the uniformity of thin films deposited on the plurality of substrates located in the first and second spaces may be changed.

In the substrate processing apparatus in accordance with the embodiment of the present disclosure, the plurality of heater members 1510, 1520, 1530, 1540 and 1550 and the power supply terminals 1510a, 1520a, 1530a, 1540a and 1550a may be asymmetrically arranged in the first and second spaces A1 and A2. Alternatively, the pattern of the heater members arranged in the first space may be different from the pattern of the heater members arranged in the second space. Thus, the temperature distribution of the substrate located in the first space may be different from the temperature distribution of the substrate which is located in the second space after being moved from the first space by the rotation of the susceptor.

Therefore, the heater members and the power supply terminals may be asymmetrically arranged or the pattern of the heater members may be different between when the substrate is located in the first space and when the substrate is located in the second space. Thus, the substrate processing apparatus in accordance with the embodiment of the present disclosure may prevent a decrease in uniformity of the thin films deposited on the substrate.

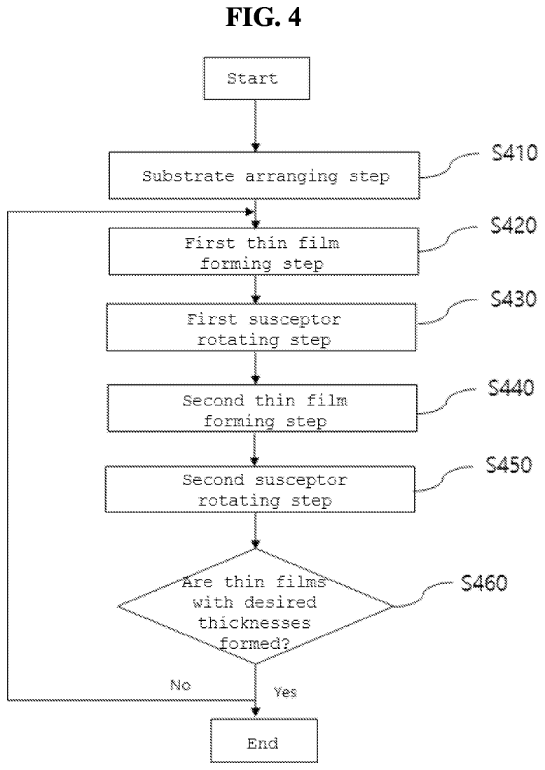

FIG. 4 is a process flowchart illustrating a substrate processing method in accordance with an embodiment of the present disclosure.

The substrate processing method in accordance with the embodiment of the present disclosure processes a substrate by using a substrate processing apparatus which includes a chamber including a first space and a second space that does not overlap the first space, a rotatable susceptor configured to support one or more substrates in the first and second spaces, a first injection unit facing the susceptor and configured to inject a gas into the first space, and a second injection unit facing the susceptor and configured to inject a gas into the first space. Referring to FIG. 4, the substrate processing method includes a substrate arranging step S410, a first thin film forming step S420, a first susceptor rotating step S430 and a second thin film forming step S440.

The substrate arranging step S410 includes arranging one or more first substrate under the first injection unit and arranging one or more second substrates under the second injection unit. The first injection unit faces the susceptor arranged across the first and second spaces in the chamber and injects two or more different gases into the first space, and the second injection unit faces the susceptor and injects two or more different gases into the second space.

The first thin film forming step S420 includes forming a thin film with a preset thickness by repeating, one or more times, a process of sequentially injecting a source gas and a reactant gas toward the first substrate and the second substrate through the first injection unit and the second injection unit, respectively.

The first susceptor rotating step S430 includes moving the first substrate to under the second injection unit and moving the second substrate to under the first injection unit, by rotating the susceptor at a predetermined angle.

The second thin film forming step S440 includes forming a thin film with a preset thickness by repeating, one or more times, a process of alternately injecting the source gas and the reactant gas toward the second substrate and the first substrate through the first injection unit and the second injection unit, respectively.

When the source gas and the reactant gas are alternately injected to form the thin films in the first and second thin film forming steps S420 and S440, the source gas or the reactant gas may be injected in a plasma state toward the substrate.

When the source gas is plasma-treated and injected, the inert source gas may be activated to generate a large quantity of radicals and ions. Thus, the source gas can be decomposed even at low temperature, and impurities included in the source gas itself can be effectively removed. When the reactant gas is plasma-treated and injected, the density of the thin film may be improved to enhance the quality of the thin film.

Plasma may be implemented as direct plasma or remote plasma generated by applying RF power into the space where the source gas stays, depending on an electrode structure.

In the first and second thin film forming steps S420 and S440, the susceptor may be stopped when the source gas or the reactant gas is injected.

The substrate processing method may further include a second susceptor rotating step S450 after the second thin film forming step S440, the second susceptor rotating step S450 including moving the first substrate to under the first injection unit and moving the second substrate to under the second injection unit by rotating the susceptor at a predetermined angle.

According to the substrate processing method in accordance with the embodiment of the present disclosure, the first thin film forming step S420, the first susceptor rotating step S430, the second thin film forming step S440 and the second susceptor rotating step S450 may be alternately repeated to form a thin film with a preset thickness. The substrate processing method may further include step S460 of checking whether a thin film with a desired thickness is formed. Then, the first thin film forming step S420, the first susceptor rotating step S430, the second thin film forming step S440 and the second susceptor rotating step S450 are repeated until the thin film with the desired thickness is formed.

In the first and second thin film forming steps S420 and S440, the susceptor may be stopped when the source gas or the reactant gas is injected.

In the first and second thin film forming steps S420 and S440, a purge gas may be injected during the time period between a point of time that the source gas is injected and a point of time that the reactant gas is injected or the time period between a point of time that the reactant gas is injected and a point of time that the source gas is injected.

The purge gas may include a first purge gas injected during the time period between the point of time that the source gas is injected and the point of time that the reactant gas is injected and a second purge gas injected during the time period between the point of time that the reactant gas is injected and the point of time that the source gas is injected. At this time, one or more of the first and second purge gases may be injected in a plasma state toward the substrate. When the first and second purge gases are plasma-treated and injected, the top, bottom and sidewalls of a pattern formed on the thin film may be selectively deposited. Furthermore, when the purge gas is plasma-treated and injected on a thin film, hydrogen included in the surface of the thin film may be removed to modify the surface of the thin film, which makes it possible to form a thin film with high selectivity.

The source gas or the reactant gas other than one or more of the first and second purge gases may also be injected in a plasma state toward the substrate.

The chamber 1100 of the substrate processing apparatus may further include a third space A3 between the first and second spaces A1 and A2. The third space A3 may include a third injection unit 1430 configured to inject a third purge gas toward the susceptor. The third injection unit 1430 may inject the third purge gas toward the susceptor in the first and second susceptor rotating steps S430 and S450. At this time, the third purge gas may be injected in a plasma state toward the substrate. Then, a plasma treatment may be performed on the thin film formed on the substrate.

The third injection unit 1430 may inject the third purge gas toward the susceptor, when the source gas or the reactant gas is injected in the first and second thin film forming steps S420 and S440. Then, a plasma treatment may be performed on the thin film formed on the substrate.

The third injection unit 1430 may inject the third purge gas toward the susceptor, when the source gas or the reactant gas is injected in the first and second thin film forming steps S420 and S440. At this time, the third purge gas may be injected in a plasma state toward the substrate.

The substrate processing method in accordance with the embodiment of the present disclosure may include performing a plasma treatment on the thin film formed on the substrate. When such a plasma treatment is performed on a deposited thin film, the electrical and optical characteristics of the thin film may be improved, and the surface modification characteristic of the thin film, such as hydrophobicity or hydrophilicity, may be improved, which makes it possible to improve the uniformity of the thin films as a whole.

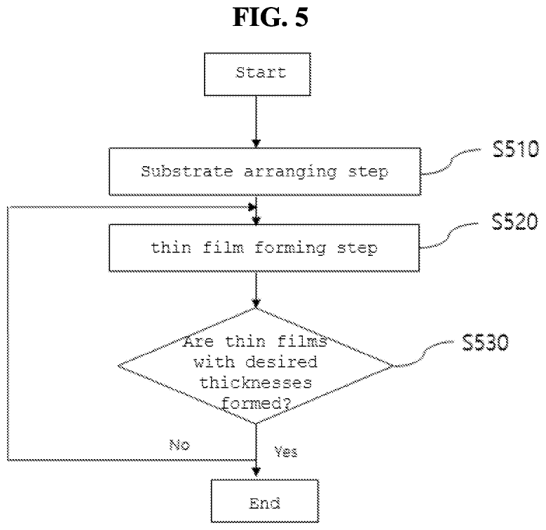

FIG. 5 is a process flowchart illustrating a substrate processing method in accordance with another embodiment of the present disclosure.

The substrate processing method in accordance with the another embodiment of the present disclosure processes a substrate by using a substrate processing apparatus which includes a chamber including a first space and a second space that does not overlap the first space, a rotatable susceptor configured to support one or more substrates in the first and second spaces, a first injection unit facing the susceptor and configured to inject a gas into the first space, and a second injection unit facing the susceptor and configured to inject a gas into the first space. Referring to FIG. 5, the substrate processing method includes a substrate arranging step S510 and a thin film forming step S520.

The substrate arranging step S510 includes arranging one or more first substrate under the first injection unit and arranging one or more second substrates under the second injection unit. The first injection unit faces the susceptor arranged across the first and second spaces in the chamber and injects two or more different gases into the first space, and the second injection unit faces the susceptor and injects two or more different gases into the second space.

The thin film forming step S520 includes forming a thin film with a preset thickness by repeating, one or more times, a process of sequentially injecting a source gas and a reactant gas toward the first substrate and the second substrate through the first injection unit and the second injection unit, respectively.

At this time, the thin film forming step S520 may further include injecting the source gas through a first gas inject flow path and injecting the reactant gas through a second gas inject flow path different from the first gas inject flow path.

In the injecting of the source gas, the source gas may be injected through the first gas inject flow path formed in a protruding electrode of a first electrode. In the injecting of the reactant gas, the reactant gas may be injected through the second gas inject flow path between the inner surface of an opening of a second electrode, formed at a position corresponding to the protruding electrode, and the side surface of the protruding electrode.

When the inner space of the chamber 1100 is divided into two spaces, i.e. the first and second spaces A1 and A2 with a third space A3 set to the boundary therebetween, the susceptor 1300 may be rotated by 180 degrees in the first susceptor rotating step S430. However, the rotation angle of the susceptor may be set to various angles such as 90°, 180°, 270° and the like according to the number of divided spaces and the process condition.

As such, a first thin film and a second thin film are sequentially formed on the first substrate W1, and the second thin film and the first thin film are sequentially formed on the second substrate W2. This process may improve the uniformity of the thin films deposited on the plurality of substrates.

When the susceptor is rotated only in the same direction in the first and second susceptor rotating steps S430 and S450, a difference occurs between the time during which a substrate adjacent to a purge gas injection unit is exposed to the purge gas injection unit and the time during which a substrate that is not adjacent to the purge gas injection unit is exposed to the purge gas injection unit.

That is, when the rotation direction of the susceptor is fixed to one direction, the substrate adjacent to the purge gas injection unit based on the rotation direction of the susceptor always passes through the purge gas injection unit earlier than the substrate which is not adjacent to the purge gas injection unit based on the rotation direction of the susceptor. Therefore, the time during which the substrate that is not adjacent to the purge gas injection unit based on the rotation direction of the susceptor is exposed to the first or second space, where the thin film is formed, before the substrate is passed through the purge region into the purge gas is injected, becomes longer than the substrate adjacent to the purge gas injection unit based on the rotation direction of the susceptor. For this reason, the uniformity of thin films deposited on the plurality of substrates may be reduced.

Therefore, when the susceptor is rotated in one direction in the first susceptor rotating step S430, the susceptor may be alternately rotated in another direction in the second susceptor rotating step S450. When thin films are formed on the plurality of substrates by a predetermined times, for example, N times, the susceptor may be rotated N/2 times in one direction, and rotated N/2 times in another direction, which makes it possible to improve the uniformity of the thin films deposited on the plurality of substrates.

In general, the reaction space inside the chamber may be asymmetrically formed. As described above, the heater members for heating the substrates may be concentrically arranged under the susceptor, and the power supply terminals are formed in places.

As such, a structural problem inside the chamber or the influence of the power supply terminals of the heater, formed under the susceptor, may change the uniformity of thin films deposited on the substrates located in the first and second spaces A1 and A2.

Thus, the embodiment of the present disclosure may minimize the structural problem inside the chamber or the influence of the power supply terminals, thereby improving the uniformity of the thin films deposited on the substrates located in the first and second spaces A1 and A2.

According to the above-described substrate processing method in accordance with the embodiment of the present disclosure, the first and second thin films with the predetermined thicknesses may be formed on the substrates W1 and W2 located in the first and second spaces A1 and A2, respectively, which makes it possible to improve the uniformity of the thin films deposited on the first and second substrates W1 and W2.

While various embodiments have been described above, it will be understood to those skilled in the art that the embodiments described are by way of example only. Accordingly, the disclosure described herein should not be limited based on the described embodiments.

1. A substrate processing apparatus comprising:
a chamber comprising a first space and a second space which does not overlap the first space;
a rotatable susceptor arranged across the first and second spaces in the chamber, and configured to support one or more substrates in the first space and support one or more substrates in the second space;
a first injection unit facing the susceptor in the first space, and configured to inject two or more different gases into the first space; and
a second injection unit facing the susceptor in the second space, and configured to inject two or more different gases into the second space,
wherein each of the first and second injection units comprises:
a first gas inject flow path configured to inject a first gas; and
a second gas inject flow path configured to inject a second gas different from the first gas.

2. The substrate processing apparatus of claim 1, wherein at least one injection unit of the first and second injection units forms a thin film on the substrate by alternately injecting the first and second gases into the first or second space.

3. The substrate processing apparatus of claim 2, wherein the susceptor is stopped when the first or second gas is injected.

4. The substrate processing apparatus of claim 2, wherein through any one of the first and second gas inject flow paths, a purge gas is injected after the first or second gas is injected.

5. The substrate processing apparatus of claim 2, wherein the first or second gas is injected in a plasma state toward the substrate.

6. The substrate processing apparatus of claim 5, wherein the second gas is a reactant gas.

7. The substrate processing apparatus of claim 4, wherein the purge gas comprises:
a first purge gas injected during a time period between a point of time that the first gas is injected and a point of time that the second gas is injected; and
a second purge gas injected during a time period between a point of time that the second gas is injected and a point of time that the first gas is injected,
wherein at least one of the first and second purge gases is injected in a plasma state toward the substrate.

8. The substrate processing apparatus of claim 7, wherein the first or second gas is injected in a plasma state toward the substrate.

9. The substrate processing apparatus of claim 5, wherein the first or second injection unit comprises an electrode configured to inject the first or second gas in a plasma state toward the substrate.

10. The substrate processing apparatus of claim 7, wherein the first or second injection unit comprises an electrode configured to inject the first or second purge gas in a plasma state toward the substrate.

11. The substrate processing apparatus of claim 8, wherein the first or second injection unit comprises an electrode configured to inject the first or second purge gas in a plasma state toward the substrate.

12. The substrate processing apparatus of claim 9, wherein the electrode comprises a first electrode having a plurality of protruding electrodes formed thereon and a second electrode having openings formed at positions corresponding to the protruding electrodes, such that the protruding electrodes are inserted into the openings, and
wherein RF power is applied to at least any one of the first and second electrodes in order to generate plasma between the side surfaces of the protruding electrodes and the inner surfaces of the openings of the second electrode.

13. The substrate processing apparatus of claim 12, wherein the first gas is injected through the first gas inject flow path extended to the protruding electrodes, and
the second gas is injected through a space between the side surfaces of the protruding electrodes and the inner surfaces of the openings of the second electrode.

14. The substrate processing apparatus of claim 2, wherein the chamber further comprises a third space between the first and second spaces,
wherein the third space comprises a third injection unit configured to inject a third purge gas toward the susceptor.

15. The substrate processing apparatus of claim 14, wherein the third purge gas is injected in a plasma state toward the substrate.

16. The substrate processing apparatus of claim 15, wherein the third injection unit comprises an electrode configured to inject the third purge gas in a plasma state toward the substrate.

17. The substrate processing apparatus of claim 15, wherein the electrode comprises a third electrode having a protruding electrode formed thereon and a fourth electrode having an opening formed at a position corresponding to the protruding electrode, such that the protruding electrode is inserted into the opening, and
wherein RF power is applied to at least any one of the third and fourth electrodes in order to generate plasma between a side surface of the protruding electrode and an inner surface of the opening of the fourth electrode.

18. The substrate processing apparatus of claim 2, wherein a plasma treatment is performed on the thin film formed on the substrate.

19. The substrate processing apparatus of claim 1, further comprising a heater installed under the susceptor and comprising power supply terminals and heater members formed in a predetermined pattern.

20. The substrate processing apparatus of claim 19, wherein the power supply terminals formed in the first space and the power supply terminals formed in the second space are asymmetrically arranged.

21-41. (canceled)

42. The substrate processing apparatus of claim 10, wherein the electrode comprises a first electrode having a plurality of protruding electrodes formed thereon and a second electrode having openings formed at positions corresponding to the protruding electrodes, such that the protruding electrodes are inserted into the openings, and
wherein RF power is applied to at least any one of the first and second electrodes in order to generate plasma between the side surfaces of the protruding electrodes and the inner surfaces of the openings of the second electrode.

43. The substrate processing apparatus of claim 11, wherein the electrode comprises a first electrode having a plurality of protruding electrodes formed thereon and a second electrode having openings formed at positions corresponding to the protruding electrodes, such that the protruding electrodes are inserted into the openings, and
wherein RF power is applied to at least any one of the first and second electrodes in order to generate plasma between the side surfaces of the protruding electrodes and the inner surfaces of the openings of the second electrode.
